(19) United States
(12) Patent Application Publication
(10) Pub. No.: US 2016/0011054 A1
(43) Pub. Date: Jan. 14, 2016

(54) THERMAL IMAGING SYSTEMS WITH VACUUM-SEALING LENS CAP AND ASSOCIATED WAFER-LEVEL MANUFACTURING METHODS

(71) Applicant: OmniVision Technologies, Inc., Santa Clara, CA (US)

(72) Inventor: Dominic Massetti, San Jose, CA (US)

(21) Appl. No.: 14/329,230

(22) Filed: Jul. 11, 2014

(51) Int. Cl. G01J 5/08; G01J 5/10; H05K 3/30; H04N 5/33

(52) U.S. Cl. CPC G01J 5/0806; H04N 5/33; G01J 5/10; H05K 3/30; G01J 2005/0081

(57) ABSTRACT

A thermal imaging system with a vacuum-sealing lens cap, includes (a) a thermal image sensor having an array of temperature sensitive pixels for detecting thermal radiation, and (b) a lens sealed to the thermal image sensor for imaging thermal radiation from a scene onto the array of temperature sensitive pixels and sealing a vacuum around the temperature sensitive pixels. A wafer-level method for manufacturing a thermal imaging system with a vacuum-sealing lens cap includes sealing a lens wafer, having a plurality of lenses, to a sensor wafer having a plurality of thermal image sensors each having an array of temperature sensitive pixels, to seal, for each of the plurality of thermal image sensors, a vacuum around the temperature sensitive pixels.

### BACKGROUND

A thermal imaging system uses an array of temperature sensitive pixels to form an image of a scene from incident infrared radiation originating from the scene. All objects emit so-called black body radiation. The intensity and wavelength of black body radiation emitted by an object is a function of the temperature of the object. Black body radiation emitted by a hot object is both more intense and peaked at shorter wavelengths than black body radiation emitted by a colder object. Thus, an image formed by a thermal imaging system reflects the temperature variations of the scene viewed by the thermal imaging system.

In one class of applications, thermal imaging systems are used to obtain an image of a scene which is lit by little or no visible light, and which therefore cannot be imaged by a standard visible light camera. For example, thermal imaging systems are used for surveillance purposes and for night vision purposes. In another class of applications, thermal imaging systems are used to obtain information about a scene, which is conveyed by the infrared, as opposed to visible, radiation emitted by the objects in the scene. This class of applications includes building inspection, medical diagnostics, meteorology, and astronomy.

High-quality thermal imaging requires effectively managing the thermal properties of the thermal imaging system itself. Thermal cross talk between individual pixels of the thermal image sensor, as well as between each individual pixel and other non-pixel portions of the thermal imaging system, must be minimized to avoid blurring of the image. Therefore, the thermal image sensor of a thermal imaging system is sealed in vacuum. As a result, conventional thermal imaging systems are complex and expensive to manufacture.

### SUMMARY

In an embodiment, a thermal imaging system with a vacuum-sealing lens cap, includes (a) a thermal image sensor having an array of temperature sensitive pixels for detecting thermal radiation, and (b) a lens sealed to the thermal image sensor for imaging thermal radiation from a scene onto the array of temperature sensitive pixels and sealing a vacuum around the temperature sensitive pixels.

In an embodiment, a wafer-level method for manufacturing a thermal imaging system with a vacuum-sealing lens cap includes sealing a lens wafer, having a plurality of lenses, to a sensor wafer having a plurality of thermal image sensors each having an array of temperature sensitive pixels, to seal, for each of the plurality of thermal image sensors, a vacuum around the temperature sensitive pixels.

### BRIEF DESCRIPTION OF THE DRAWINGS

FIG. 1 illustrates a thermal imaging system with a vacuum-sealing lens cap, according to an embodiment.

FIG. 2 illustrates a wafer-level method for manufacturing a thermal imaging system with a vacuum-sealing lens cap, according to an embodiment.

FIG. 3 illustrates steps of the method of FIG. 2, according to an embodiment.

FIG. 4 illustrates steps of the method of FIG. 2, according to another embodiment.

FIG. 5 illustrates a method for forming a lens wafer including a plurality of vacuum-sealing lens caps, according to an embodiment.

FIGS. 6A, 6B, and 6C illustrate a thermal imaging system, wherein a planar side of a vacuum-sealing lens cap is sealed to a thermal image sensor along a path that circumnavigates the temperature sensitive pixel array of the thermal image sensor, according to an embodiment.

FIG. 7 illustrates a thermal imaging system in which a vacuum-sealing lens cap seals each temperature sensitive pixel in a separate respective vacuum, according to an embodiment.

FIG. 8 illustrates a thermal imaging system having a vacuum-sealing lens cap sealed to a thermal image sensor at locations interior to the temperature sensitive pixel array of the thermal image sensor, according to an embodiment.

FIG. 9 illustrates a thermal imaging system having a vacuum-sealing lens cap sealed to a thermal image sensor, wherein all contact points between the vacuum-sealing lens cap and the thermal image sensor are located outside the temperature sensitive pixel array, according to an embodiment.

FIG. 10 illustrates a thermal imaging system having a vacuum-sealing lens cap sealed to a thermal image sensor, wherein some but not all borders between pixel pockets in the thermal image sensor are recessed from the interface between the vacuum-sealing lens cap and the thermal image sensor, according to an embodiment.

FIGS. 11A and 11B illustrate a thermal imaging system having a vacuum-sealing lens cap sealed to a thermal image sensor, wherein the vacuum-sealing lens cap has a concave surface facing the thermal image sensor, according to an embodiment.

FIGS. 12A and 12B illustrate a configuration of a temperature sensitive pixel, according to an embodiment.

FIGS. 13A and 13B illustrate another configuration of a temperature sensitive pixel, according to an embodiment.

### DETAILED DESCRIPTION OF THE EMBODIMENTS

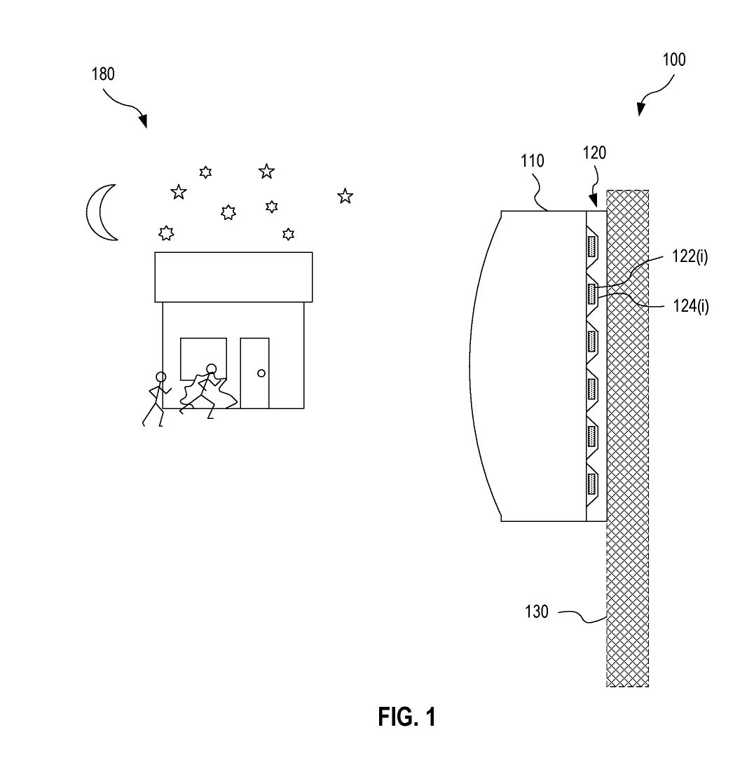

FIG. 1 illustrates, in cross-sectional side-view, one exemplary thermal imaging system 100 with a vacuum-sealing lens cap 110. Thermal imaging system 100 includes vacuum-sealing lens cap 110 and a thermal image sensor 120. Thermal image sensor 120 includes an array of temperature sensitive pixels 122, each suspended in a respective pocket 124. For clarity of illustration, only one temperature sensitive pixel 122 and one pocket 124 are labeled in FIG. 1. Vacuum-sealing lens cap 110 seals a vacuum in pockets 124 around temperature sensitive pixels 122. Mechanical support structures between temperature sensitive pixels 122 and pockets 124 extend into the vacuum sealed by lens cap 110 to suspend temperature sensitive pixels 122 in pockets 124. For clarity of illustration, such mechanical support structures are not depicted in FIG. 1.

For the purposes of the present disclosure, the term “vacuum” refers to a pressure that is reduced as compared to the standard pressure of one bar. For example, “vacuum” may refer to a pressure that is reduced to about one percent or less of one bar.

Vacuum-sealing lens cap 110 provides a simple and cost-effective solution to vacuum sealing of temperature sensitive pixels 122, as compared to conventional systems. Vacuum sealing lens cap 110 serves two functions: (1) imaging of thermal radiation from a scene 180 onto thermal image sensor 120 and (2) vacuum-sealing of temperature sensitive pixels 122. Hence, as compared to conventional thermal imaging systems, thermal imaging system 100 requires fewer components. The cost of materials for thermal imaging system 100 may be further reduced by forming vacuum-sealing lens cap 110 from a low-cost material such as silicon. In general, vacuum-sealing lens cap 110 is formed from material at least partially transmissive to thermal radiation such as mid-wavelength infrared (MWIR) radiation and/or long-wavelength infrared (LWIR) radiation.

Thermal imaging system 100 may be manufactured at the wafer-level, thus benefitting from the low cost of wafer-level manufacturing method. In certain embodiments, vacuum-sealing lens cap 110 is formed from a lens wafer that is molded by hot-pressing a powder material such as silicon or a ceramic powder. Hot-pressing is a very inexpensive molding technique capable of providing optical quality sufficient for thermal imaging applications. The spatial resolution requirements of thermal imaging systems are less strict than those of many visible imaging systems. In an embodiment, the center-to-center distance between nearest neighbor temperature sensitive pixels 122 is in the range between 15 micron and 50 micron, for example 25 micron. Thus, the optical surfaces of vacuum-sealing lens cap 110 may be manufactured using powder hot-pressing. Accordingly, thermal imaging system 100 may, in addition to having low cost of materials, be manufactured at minimal process-associated cost.

Optionally, thermal imaging system 100 includes an image signal processing (ISP) circuit board 130 communicatively coupled with thermal image sensor 120. ISP circuit board 130 performs at least one of (a) processing thermal images captured by thermal image sensor 120 and (b) controlling functionality of thermal image sensor 120. Thermal image sensor 120 may be surface mounted onto ISP circuit board 130. For clarity of illustration, FIG. 1 does not show electrical connections between temperature sensitive pixels 122 and ISP circuit board 130.

In the exemplary scenario illustrated in FIG. 1, thermal imaging system 100 functions as a night-time surveillance camera. However, thermal imaging system 100 may be used in other thermal imaging applications including, but not limited to, building inspection, medical diagnostics, meteorology, and astronomy.

Pockets 124 may have shape different from that depicted in FIG. 1, without departing from the scope hereof. Likewise, thermal image sensor 120 may include a different number of temperature sensitive pixels 122 than illustrated in FIG. 1, without departing from the scope hereof. For example, thermal image sensor 120 may include a rectangular array of M×N temperature sensitive pixels 122, where M and N are positive integers. In one embodiment, M=160 and N=120. In another embodiment, M=240 and N=160. Also without departing from the scope hereof, vacuum-sealing lens cap 110 may have shape different from that depicted in FIG. 1, and for example be a meniscus lens or a plano-convex lens having spherical or aspherical properties.

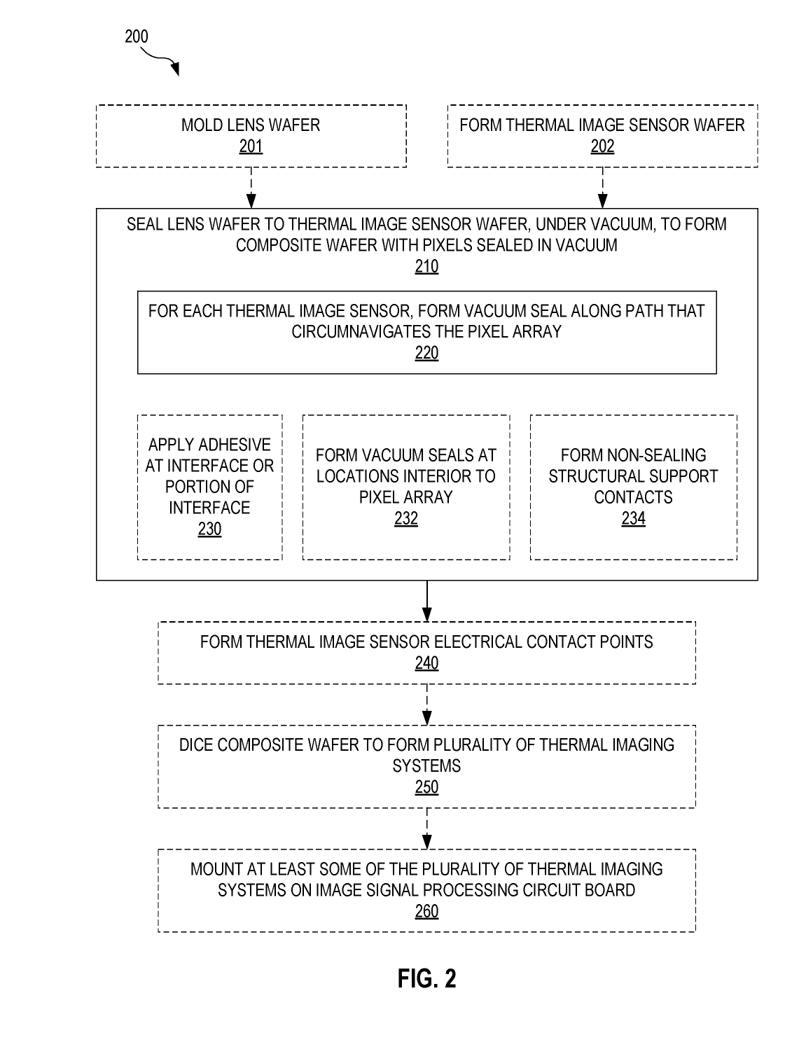

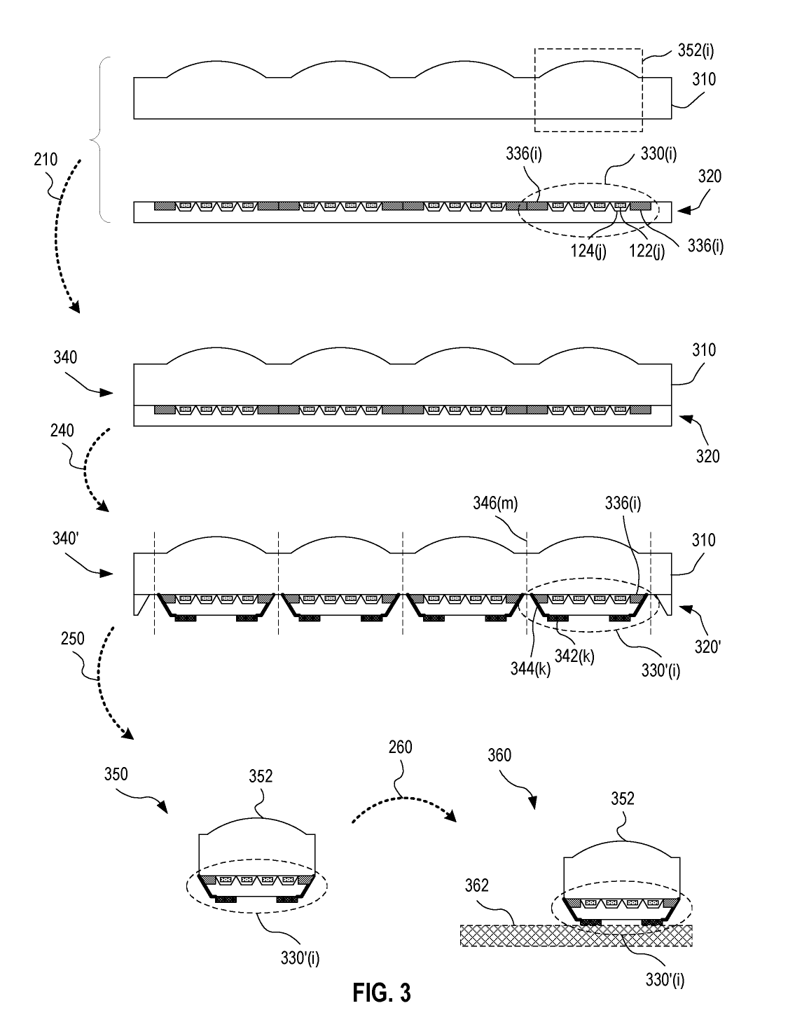

FIG. 2 is a flowchart illustrating one exemplary wafer-level method 200 for manufacturing a thermal imaging system with a vacuum-sealing lens cap, such as thermal imaging system 100 of FIG. 1. FIG. 3 is a series of diagrams that illustrate, by example, steps of wafer-level method 200. FIGS. 2 and 3 are best viewed together.

In a step 210, a lens wafer is sealed to a thermal image sensor wafer. The lens wafer includes a plurality of lenses, such as vacuum-sealing lens cap 110 (FIG. 1). The thermal image sensor wafer includes a respective plurality of thermal image sensors, such as thermal image sensor 120 (FIG. 1), each having its temperature sensitive pixels suspended in pockets of the thermal image sensor. Step 210 is performed under vacuum to form a composite wafer with a vacuum sealed in the pockets of the thermal image sensors. For example, a lens wafer 310 (FIG. 3) is sealed to a thermal image sensor wafer 320 (FIG. 3) to form a composite wafer 340 (FIG. 3). Lens wafer 310 includes a plurality of lenses 352 which are embodiments of vacuum-sealing lens cap 110 (FIG. 1); for clarity of illustration, only one lens 352 is labeled in FIG. 3. Similarly to the discussion of vacuum-sealing lens cap 110 (FIG. 1), lens 352 may have shape different from that shown in FIG. 3. Thermal image sensor wafer 320 includes a plurality of image thermal image sensors 330; for clarity of illustration, only one thermal image sensor 330 is labeled in FIG. 3. Thermal image sensor 330 is an embodiment of thermal image sensor 120 (FIG. 1). Each thermal image sensor 330 includes an array of temperature sensitive pixels 122 (FIG. 1) suspended in respective pockets 124 (FIG. 1). Each thermal image sensor 330 further includes peripheral electronic circuitry 336 that relays electrical signals between temperature sensitive pixels 122 and electronics located externally to thermal image sensor 330.

Without departing from the scope hereof, lens wafer 310 may include a different number of lenses 352, thermal image sensor wafer 320 may include a different number of thermal image sensors 330, thermal image sensor 330 may include a different number of temperature sensitive pixels 122, pockets 124 may be of different shape, lenses 352 may be of different shape, and peripheral electronic circuitry 336 may be positioned differently, as compared to the illustration of FIG. 3. For clarity of illustration, mechanical support structures for holding temperature sensitive pixels 122 in pockets 124 are not shown in FIG. 3.

In an embodiment, step 210 includes a step 220 of, for each thermal image sensor of the thermal image sensor wafer, forming a vacuum seal along a path that circumnavigates the array of temperature sensitive pixels of the thermal image sensor. For example, for each thermal image sensor 330, composite wafer 340 includes a seal at the interface between lens wafer 310 and thermal image sensor wafer 320, which circumnavigates the array of temperature sensitive pixels 122.

Vacuum seals formed in step 210 may be formed using bonding methods known in the art, such as direct bonding, plasma activated bonding, eutectic bonding, or transient liquid phase diffusion bonding. In certain embodiments, step 210 includes a step 230 of applying an adhesive at the interface between the lens wafer and the thermal image sensor wafer to form a hermetically sealing bond between the lens wafer and the thermal image sensor wafer at the locations of the adhesive. The adhesive may be applied at the vacuum-sealing paths of step 220 and other vacuum-sealing associated portions of the interface. For example, an adhesive is disposed between the two surfaces of lens wafer 310 and thermal image sensor wafer 320, respectively, that are to be bonded, at least in locations needed to perform step 220.

Optionally, step 210 includes a step 232, wherein, for at least some of the thermal image sensors, one or more vacuum seals are formed at locations interior to the array of temperature sensitive pixels. In one example, each temperature sensitive pixel, such as temperature sensitive pixel 122, is individually vacuum-sealed. In another example, two or more sub-portions of the array of temperature sensitive pixels 122 are individually vacuum-sealed.

Step 210 may further include a step 234 of forming contacts between the lens wafer and the thermal image sensor wafer at interface locations not associated with vacuum-sealing. These contacts may serve to provide structural support, for example to counteract a vacuum-induced attractive force between a lens 352 and a corresponding thermal image sensor 330. Such structural support may prevent warping of thermal image sensor wafer 330.

In an embodiment, wafer-level method 200 includes a step 240 of forming electrical contact points on the thermal image sensor wafer. These electrical contact points provide an interface at which external electronic circuitry, such as ISP circuit board 130 (FIG. 1), may communicate with a thermal image sensor of the thermal image sensor wafer. For example, thermal image sensor wafer portion 320 of composite wafer 340 is modified to form a composite wafer 340′ (FIG. 3) with a modified thermal image sensor wafer 320′. Each modified thermal image sensor 330′ of thermal image sensor wafer 320′ includes electrical contact pads 342 that are connected to peripheral electronic circuitry 336 via electrical connections 344. For clarity of illustration, only one modified thermal image sensor 330′, only one electrical contact pad 342, and only one electrical connection 344 are labeled in composite wafer 340′. The specific electrical contact configurations depicted in FIG. 3 are T-contacts. Step 240 may utilize other technologies than T-contacts without departing from the scope hereof. Step 240 may form T-contacts by etching through thermal image sensor wafer 320, from the surface facing away from lens wafer 310, to reach peripheral electronic circuitry 336. Electrically conductive pads are produced on the surface of thermal image sensor wafer 320 facing away from lens wafer 310 to form electrical contact pads 342. Electrically conductive traces are deposited between peripheral electronic circuitry 336 and electrical contact pads 342 to form electrical connections 344.

In an embodiment, wafer-level method 200 further includes a step 250 of dicing the composite wafer formed in step 210 or step 220 to produce a plurality of thermal imaging systems. For example, composite wafer 340′ is diced along dicing lines 346 to produce a plurality of thermal imaging systems 350 (FIG. 3). Thermal imaging system 350 includes thermal image sensor 330′ and lens 352. Lens 352 functions as a vacuum-sealing lens cap. Thermal imaging system 350 is an embodiment of thermal imaging system 100 (FIG. 1). Lens 352 and thermal image sensor 330′ are embodiments of vacuum-sealing lens cap 110 (FIG. 1) and thermal image sensor 120 (FIG. 1), respectively.

Wafer-level method 200 may include a step 260, wherein at least some of the plurality of thermal imaging systems 350 are mounted to respective ISP circuit boards. For example, for at least some of the plurality of thermal imaging systems 350, thermal imaging system 350 is mounted to an ISP circuit board 362 to form a thermal imaging system 360 (FIG. 3). ISP circuit board 362 is an embodiment of ISP circuit board 130 of FIG. 1. Thermal imaging system 350 is mounted to ISP circuit board 362 such that at least some of electrical contact pads 342 are in electrical contact with electronic circuitry of ISP circuit board 362. In one example, thermal imaging system 350 is solder bump bonded to ISP circuit board 362 using methods known in the art such as reflow soldering. Thermal imaging system 360 is an embodiment of thermal imaging system 100 (FIG. 1).

Optionally, wafer-level method 200 includes one or both of step 201 and 202 of producing the lens wafer and the thermal image sensor wafer, respectively. In step 201, the lens wafer, such as lens wafer 310 (FIG. 3), is molded. Step 201 may utilize, for example, methods known in the art such as injection molding, hot-pressing, isostatic pressing, die pressing, slip casting, and/or sintering. In an example, step 201 molds lens wafer 310 from one or more materials such as silicon, aluminum oxinitride, magnesium aluminate spinel, plastic such as POLY IR® 2 (brand name, infrared transmissive plastic available from Fresnel Technologies), or REAI® glass (brand name for a glass composed of oxides of elements Sc, Y, La, Ce, Pr, Nd, Sm, Eu, Gd, Tb, Dy, Ho, Er, Tm, Yb, and Lu, as disclosed in U.S. Pat. No. 6,482,758).

In step 202, the thermal image sensor wafer, such as thermal image sensor wafer 320 (FIG. 3), is formed. Step 202 may utilize methods known in the art. In an embodiment, step 202 produces thermal image sensor wafer, at least in part, using complementary-metal-oxide semiconductor (CMOS) fabrication methods.

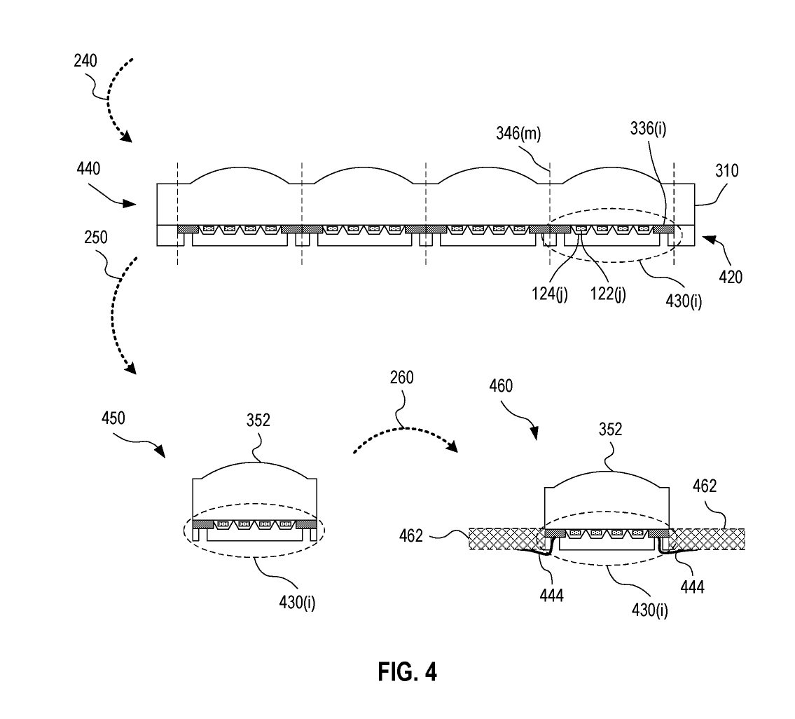

FIG. 4 is a series of diagrams that illustrate an alternative example of optional steps 240, 250, and 260 of wafer-level method 200 (FIG. 2). The example of FIG. 4 illustrates the use of wire bonding to make electrical connections to the thermal image sensors.

In this example, step 240 (FIG. 2) modifies thermal image sensor wafer 320 (FIG. 3) of composite wafer 340 (FIG. 3) to produce a composite wafer 440 having a thermal image sensor wafer 420. Thermal image sensor wafer 420 includes a plurality of thermal image sensors 430 that are modified versions of thermal image sensor 330 (FIG. 3). Step 240 etches holes in each of thermal image sensors 430, from the side facing away from lens wafer 310 (FIG. 3), to expose at least a portion of peripheral electronic circuitry 336 (FIG. 3). For clarity of illustration, only one thermal image sensor 430 is labeled in FIG. 4.

Step 250 proceeds, as discussed in connection with FIG. 3, to form a plurality of thermal imaging systems 450. Each thermal imaging system 450 includes thermal image sensor 430 and lens 352 sealed thereto. Thermal imaging system 450 is an embodiment of thermal imaging system 100 (FIG. 1). Thermal image sensor 430 is an embodiment of thermal image sensor 120 (FIG. 1).

In step 260, thermal imaging system 450 is disposed on an ISP circuit board 462 to form a thermal imaging system 460. Step 260 makes electrical connections between peripheral electronic circuitry 336 and ISP circuit board 462 by bonding wires 444 to peripheral electronic circuitry 336, through the holes formed in step 240. Wires 444 are also bonded to electronic circuitry of ISP circuit board 462 to complete electrical connections between ISP circuit board 462 and the array of temperature sensitive pixels 122 (FIG. 1). Thermal imaging system 460 is an embodiment of thermal imaging system 100 (FIG. 1). ISP circuit board 462 is an embodiment of ISP circuit board 130 (FIG. 1).

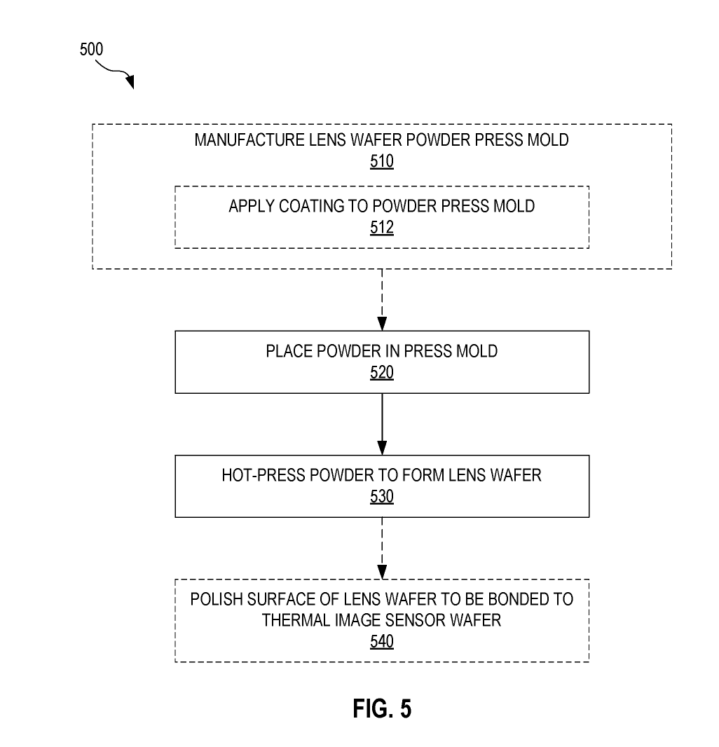

FIG. 5 illustrates one exemplary method 500 for forming a lens wafer including a plurality of vacuum-sealing lens caps, through hot-pressing a powder made of a material that is at least partially transmissive to thermal radiation. Method 500 may be used to form lens wafer 310 of FIG. 3. Method 500 is an embodiment of step 201 of wafer-level method 200 (FIG. 2).

In an optional step 510, lens wafer powder press molds are manufactured. Step 510 may utilize methods known in the art, such as diamond turning, to form mold features complementary to the shape of the lens wafer. Optionally, step 510 includes a step 512 of applying a coating to the powder press mold to ease the removal of the lens wafer subsequent to molding and/or prevent reactions between the lens wafer material and the power press mold.

In a step 520, a powder is placed in the powder press mold. The powder is composed of material that is at least partially transmissive to thermal radiation. For example, the powder is composed of material that is at least partially transmissive to MWIR radiation and/or LWIR radiation. Silicon powder is compatible with hot-pressing and is partially transmissive to MWIR and LWIR radiation. Hot-pressing of silicon is disclosed, for example, in U.S. Pat. No. 8,105,923 and in “Hot Pressing and Characterization of Powder Based Silicon Substrates for Photovoltaic Applications”, Philip Juven, July 2012. Thus, in one embodiment of step 520, the powder is silicon powder, for example with particle sizes in the range from 10 micron to 50 micron. Aluminum oxinitride and magnesium aluminate spinel are partially transmissive to MWIR radiation. As disclosed in “Transparent Ceramics Enable Large Durable, Multifunctional Optics”, Ramisetti et al., Photonics Spectra June 2014, pp. 58-62, which is incorporated by reference herein in its entirety, aluminum oxinitride and magnesium aluminate spinel may be hot-pressed to form optical lenses. Therefore, in another embodiment of step 520, the powder is aluminum oxinitride powder or magnesium aluminate spinel powder.

In a step 530, the powder is hot-pressed to form the lens wafer. Pressure and heat are applied to the powder to form the lens wafer. In one embodiment, pressure and heat are applied simultaneously. In another embodiment, step 530 first applies pressure and then, subsequently, applies simultaneous pressure and heat.

In an optional step 540, the lens wafer formed in step 540 is polished. The polish is applied to the surface of the lens wafer, which is to be bonded to the thermal image sensor wafer. Step 540 may serve to improve the vacuum-sealing properties of the lens wafer, and/or improve thickness and uniformity properties of the lens wafer.

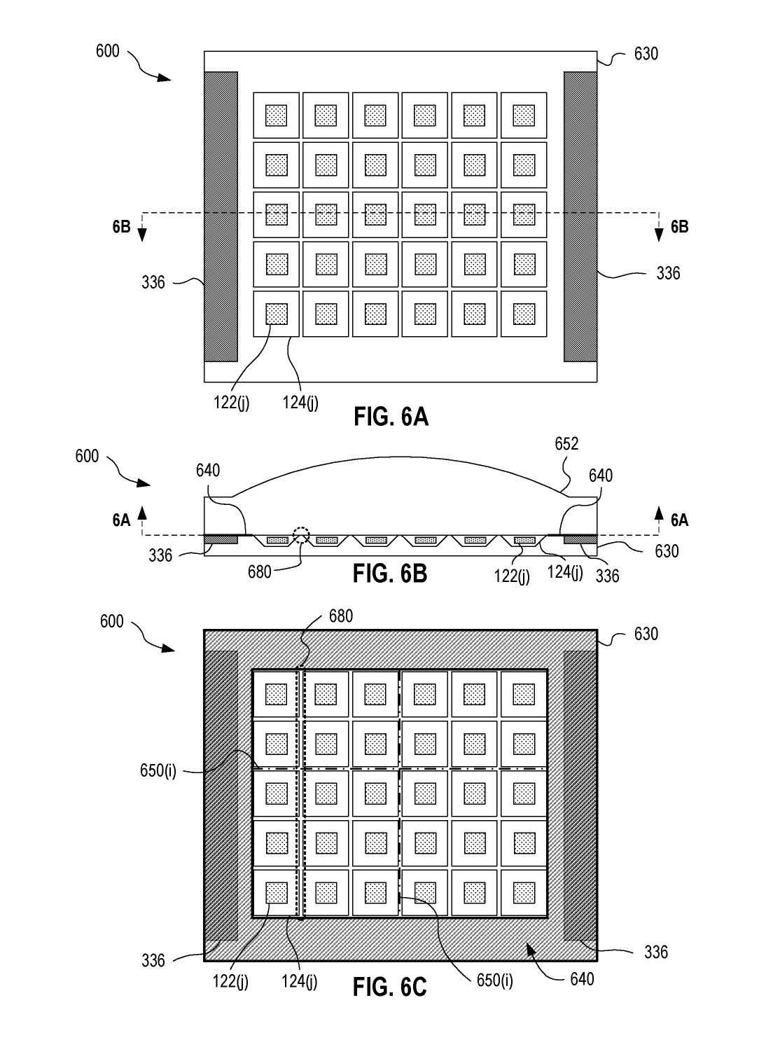

FIGS. 6A, 6B, and 6C illustrate one exemplary thermal imaging system 600, wherein a planar side of a vacuum-sealing lens cap is sealed to a thermal image sensor along a path that circumnavigates the temperature sensitive pixel array of the thermal image sensor, thereby vacuum-sealing the temperature sensitive pixel array. Thermal imaging system 600 is an embodiment of thermal imaging system 100 (FIG. 1) and may be manufactured using wafer-level method 200 (FIG. 2). FIGS. 6A and 6B show thermal imaging system 600 in cross-sectional top-view and cross-sectional side-view, respectively. The cross-section of FIG. 6A is taken along line 6A-6A in FIG. 6B. The cross-section of FIG. 6B is taken along line 6B-6B in FIG. 6A. FIG. 6C is the same view as FIG. 6A, however further including indication of vacuum-sealing areas.

Thermal imaging system 600 includes a thermal image sensor 630 and a vacuum-sealing lens cap 652 which includes a plano-convex lens. The planar side of vacuum-sealing lens cap 652 faces thermal image sensor 630. As understood by a person ordinarily skilled in the art, the planar side of vacuum-sealing lens cap 652 may deviate somewhat from being perfectly planar, without departing from the scope hereof. For example, manufacturing tolerances may produce non-flat features such as sag and/or surface roughness. Vacuum-sealing lens cap 652 is an embodiment of lens 352 (FIG. 1). The shape of the surface of vacuum-sealing lens cap 652 facing away from thermal image sensor 630 may deviate from convex and, for example, be concave or a combination of convex and concave, without departing from the scope hereof. Thermal image sensor 630 is an embodiment of thermal image sensor 330 (FIG. 3). Although not shown in FIGS. 6A-6C, thermal image sensor 630 may include electrical connections such as those formed in optional steps 240 and/or 260 of wafer-level method 200 (FIG. 2), without departing from the scope hereof. Thermal image sensor 630 includes an array of temperature sensitive pixels 122 (FIG. 1), each suspended in a pocket 124 (FIG. 1). For clarity of illustration, mechanical support structures that suspend temperature sensitive pixels 122 in pockets 124 are not shown in FIG. 6. Thermal image sensor 630 further includes peripheral electronic circuitry 336 (FIG. 3). Without departing from the scope hereof, thermal image sensor 630 may include a different number of temperature sensitive pixels 122 than illustrated in FIGS. 6A-6C, and peripheral electronic circuitry 336 may be arranged in one or more locations different from the illustration of FIGS. 6A-6C.

At the interface between vacuum-sealing lens cap 652 and thermal image sensor 630, thermal imaging system 600 includes a vacuum-sealing area 640, wherein vacuum-sealing lens cap 652 is hermetically sealed to thermal image sensor 630. FIG. 6B shows vacuum-sealing area 640 as a thick line, while FIG. 6C shows vacuum-sealing area 640 as a hatched area outlined with a thick line. Vacuum-sealing area 640 circumnavigates the array of temperature sensitive pixels 122, as illustrated in FIG. 6C. Hence, vacuum-sealing area 640 hermetically seals the array of pockets 124 housing the array of temperature sensitive pixels 122. Provided that vacuum-sealing lens cap 652 is sealed to thermal image sensor 630 under vacuum, vacuum-sealing area 640 seals a vacuum in the array of pockets 124. The exact area of the interface between vacuum-sealing lens cap 652 and thermal image sensor 630 that is occupied by vacuum-sealing area 640 may deviate from the illustration in FIGS. 6B and 6C, without departing from the scope hereof, as long as vacuum-sealing area 640 circumnavigates the array of temperature sensitive pixels 122. For example, vacuum-sealing area 640 may be an irregularly formed area. In an embodiment, thermal imaging system 600 is manufactured according to wafer-level method 200 (FIG. 2), and vacuum-sealing area 640 is formed in step 220.

Thermal image sensor 630 and vacuum-sealing lens cap 652 contact each other in locations 680 interior to the array of temperature sensitive pixels, specifically between each row of pockets 124 and between each column of pockets 124. For clarity of illustration, only one location 680, located between two columns of pockets 124, is labeled in FIGS. 6B and 6C. Locations 680 may provide structural support for thermal imaging system 600. Thus, locations 680 may prevent distortion of the shape of thermal image sensor 630 and/or vacuum-sealing lens cap 652, which may otherwise be caused by the attractive force generated by the vacuum in pockets 124.

In an embodiment, vacuum-sealing lens cap 652 is sealed to thermal image sensor 630 in one or more of locations 680, thereby forming vacuum-sealing areas 650. Vacuum-sealing areas 650 provide separate vacuum-sealing of sub-portions of the array of temperature sensitive pixels 122. Thermal imaging system 600 may include fewer or more vacuum-sealing areas 650 than shown in FIG. 6C, without departing from the scope hereof. Vacuum-sealing areas 650 are, for example, formed in step 232 of wafer-level method 200 (FIG. 2).

Optionally, vacuum-sealing area 640, and/or optional vacuum-sealing areas 650, include an adhesive for forming the vacuum seal. This adhesive may be applied in step 230 of wafer-level method 200 (FIG. 2).

In an embodiment, vacuum-sealing lens cap 652 is a silicon lens, optionally including a surface coating, vacuum-sealing lens cap 652 has thickness less than 5 millimeters, thermal image sensor 630 has side length on the order of 5 millimeters, and the convex surface of vacuum-sealing lens cap 652 has a radius of curvature of about 10 millimeters. In this embodiment, the transmission coefficient of vacuum-sealing lens cap 652 in the LWIR spectral range averages about 25 percent.

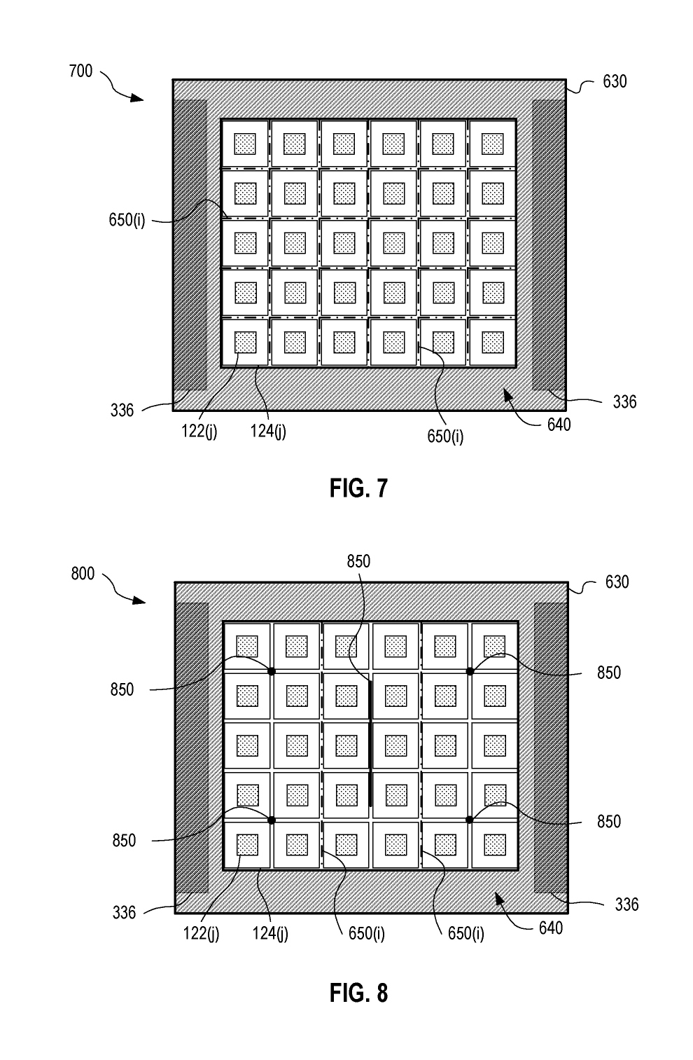

FIG. 7 illustrates one exemplary thermal imaging system 700 in which a vacuum-sealing lens cap seals each temperature sensitive pixel in a separate respective vacuum. FIG. 7 illustrates thermal imaging system 700 in cross-sectional top-view, as used in FIG. 6C. Thermal imaging system 700 is an embodiment of thermal imaging system 600 (FIGS. 6A-6C) with vacuum sealing areas 650 between each row of pockets 124 and between each column of pockets 124. For pockets 124 located along the perimeter of the array of temperature sensitive pixels 122, vacuum sealing areas 640 (FIGS. 6B and 6C) and 650 (FIG. 6C) cooperate to individually vacuum-seal each pocket 124. For pockets 124 located away from the perimeter of the array of temperature sensitive pixels 122, vacuum sealing areas 650 cooperate to individually vacuum-seal each pocket 124.

FIG. 8 illustrates one exemplary thermal imaging system 800 having a vacuum-sealing lens cap sealed to a thermal image sensor at locations interior to the temperature sensitive pixel array of the thermal image sensor. FIG. 8 illustrates thermal imaging system 700 in cross-sectional top-view, as used in FIG. 6C. Thermal imaging system 800 is an embodiment of thermal imaging system 600 (FIGS. 6A-6C), wherein vacuum-sealing lens cap 652 (FIG. 6B) is sealed to thermal image sensor 630 at sealing locations 850 interior to the array of temperature sensitive pixels 122. Sealing locations 850 may be of a variety of shapes. FIG. 8 illustrates non-limiting examples of shapes. Exemplary shapes are illustrated in FIG. 8. Sealing locations 850 do not contribute to vacuum-sealing of pockets 124. However, sealing locations 850 may improve the structural stability of thermal imaging system 800. Optionally, thermal imaging system 800 further includes one or more vacuum-sealing regions 650 (FIG. 6C).

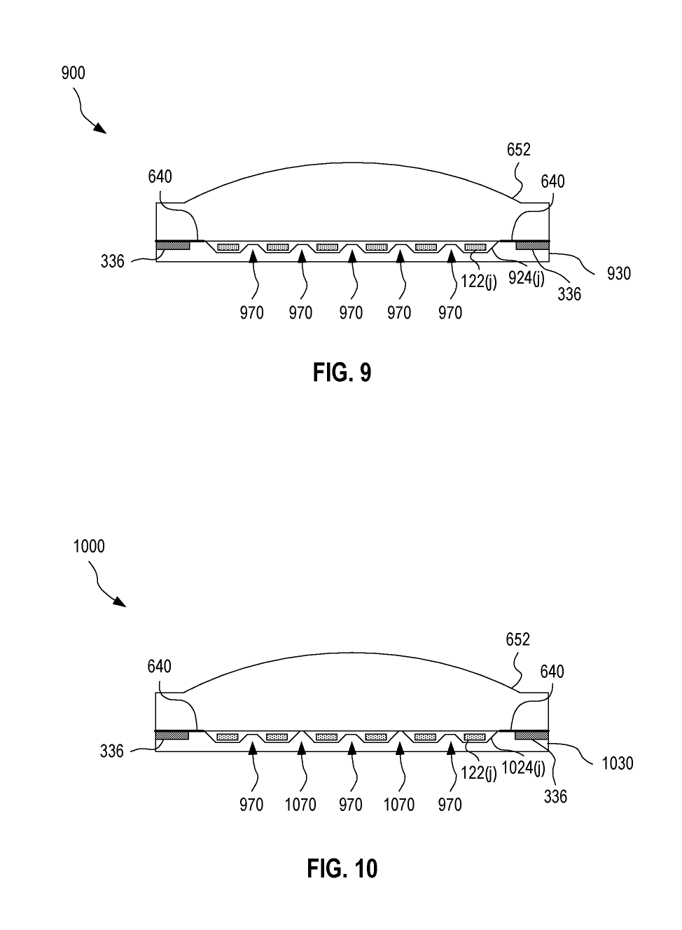

FIG. 9 illustrates one exemplary thermal imaging system 900 having a vacuum-sealing lens cap sealed to a thermal image sensor, wherein all contact points between the vacuum-sealing lens cap and the thermal image sensor are located outside the temperature sensitive pixel array. FIG. 9 illustrates thermal imaging system 900 in cross-sectional side-view, as used in FIG. 6B. Thermal imaging system 900 is an embodiment of thermal imaging system 100 (FIG. 1) and may be manufactured using wafer-level method 200 (FIG. 2).

Thermal imaging system 900 includes vacuum-sealing lens cap 652 (FIG. 6B) sealed to a thermal image sensor 930. Thermal image sensor 930 is an embodiment of thermal image sensor 120 (FIG. 1) with temperature sensitive pixels 122 suspended in pockets 924. Pocket 924 is an embodiment of pocket 124 (FIG. 1). For clarity of illustration, mechanical support structures holding temperature sensitive pixels 122 in pockets 924 are not shown in FIG. 9. Thermal image sensor 930 is similar to thermal image sensor 630 (FIGS. 6A-6C), except that borders 970 between pockets 924 are recessed from the surface of thermal image sensor 930 that is sealed to vacuum-sealing lens cap 652. Accordingly, vacuum-sealing lens cap 652 does not touch thermal image sensor 930 in areas internal to the array of temperature sensitive pixels 122. Vacuum-sealing lens cap 652 is sealed to thermal image sensor 930 in vacuum-sealing area 640 (FIGS. 6B and 6C).

FIG. 10 illustrates one exemplary thermal imaging system 1000 having a vacuum-sealing lens cap sealed to a thermal image sensor, wherein some but not all borders between pixel pockets in the thermal image sensor are recessed from the interface between the vacuum-sealing lens cap and the thermal image sensor. FIG. 10 illustrates thermal imaging system 1000 in cross-sectional side-view, as used in FIG. 6B. Thermal imaging system 1000 is an embodiment of thermal imaging system 100 (FIG. 1) and may be manufactured using wafer-level method 200 (FIG. 2).

Thermal imaging system 1000 includes vacuum-sealing lens cap 652 (FIG. 6B) sealed to a thermal image sensor 1030. Thermal image sensor 1030 is an embodiment of thermal image sensor 120 (FIG. 1) with temperature sensitive pixels 122 suspended in pockets 1024. Pocket 1024 is an embodiment of pocket 124 (FIG. 1). For clarity of illustration, mechanical support structures suspending temperature sensitive pixels 122 in pockets 1024 are not shown in FIG. 10. Thermal imaging system 1000 includes vacuum-sealing area 640 that seals a vacuum in the array of pockets 1024. Thermal image sensor 1030 is similar to thermal image sensor 630 (FIGS. 6A-6C) and thermal image sensor 930 (FIG. 9), except that some borders 970 between pockets 1024 are recessed from the surface of thermal image sensor 1030 that is sealed to vacuum-sealing lens cap 652, while other borders 1070 are not recessed from the surface of thermal image sensor 1030 that is sealed to vacuum-sealing lens cap 652. Borders 1070 touch vacuum-sealing lens cap 652. Therefore, borders 1070 may be associated vacuum-sealing areas 650 (FIG. 6C) and/or sealing locations 850 (FIG. 8), or provide structural support for thermal imaging system 1000, as discussed for thermal imaging system 600 (FIGS. 6A-6C).

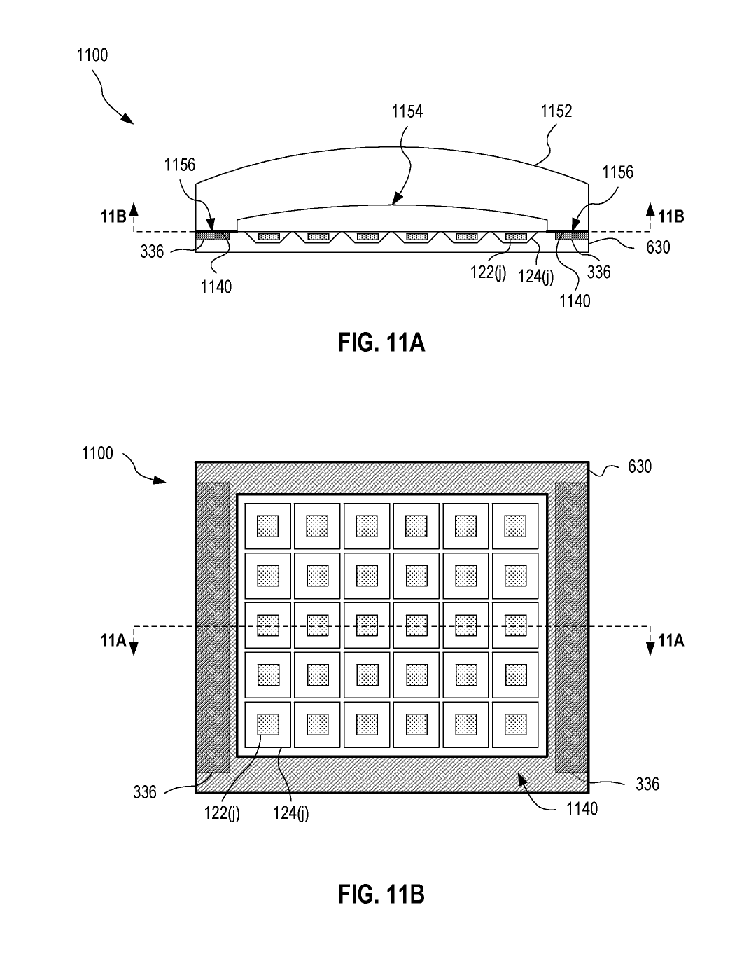

FIGS. 11A and 11B illustrate one exemplary thermal imaging system 1100 having a vacuum-sealing lens cap sealed to a thermal image sensor, wherein the vacuum-sealing lens cap has a concave surface facing the thermal image sensor. FIGS. 11A and 11B show thermal imaging system 1100 in cross-section side-view and cross-sectional top-view respectively, equivalent to the views used in FIGS. 6B and 6C. The cross-section of FIG. 11A is taken along line 11A-11A in FIG. 11B. The cross-section of FIG. 11B is taken along line 11B-11B in FIG. 11A. Thermal imaging system 1100 is an embodiment of thermal imaging system 100 (FIG. 1) and may be manufactured using wafer-level method 200 (FIG. 2). Thermal imaging system 1100 includes a vacuum-sealing lens cap 1152 sealed to thermal image sensor 630 (FIGS. 6A-6C). Vacuum-sealing lens cap 1152 includes a concave surface 1154, which faces thermal image sensor 630. Vacuum-sealing lens cap 1152 also includes a planar surface 1156 for interfacing with thermal image sensor 630.

At the interface between planar surface 1156 and thermal image sensor 630, thermal imaging system 1100 includes a vacuum-sealing area 1140, wherein vacuum-sealing lens cap 1152 is hermetically sealed to thermal image sensor 630. FIG. 11A shows vacuum-sealing area 1140 as a thick line, while FIG. 11B shows vacuum-sealing area 1140 as a hatched area outlined with a thick line. Vacuum-sealing area 1140 circumnavigates the array of temperature sensitive pixels 122, as illustrated in FIG. 11B. Hence, vacuum-sealing area 1140 hermetically seals the array of pockets 124 housing the array of temperature sensitive pixels 122. Provided that vacuum-sealing lens cap 1152 is sealed to thermal image sensor 630 under vacuum, vacuum-sealing area 1140 seals a vacuum in the array of pockets 124 and remaining space between concave surface 1154 and the array of pockets 124. The exact area of the interface between vacuum-sealing lens cap 1152 and thermal image sensor 630 that is occupied by vacuum-sealing area 1140 may deviate from the illustration in FIGS. 11A and 11B, without departing from the scope hereof, as long as vacuum-sealing area 1140 circumnavigates the array of temperature sensitive pixels 122. For example, vacuum-sealing area 1140 may be an irregularly formed area. In an embodiment, thermal imaging system 1100 is manufactured according to wafer-level method 200 (FIG. 2), and vacuum-sealing area 1140 is formed in step 220.

In an alternate embodiment of thermal imaging system 1100, thermal image sensor 630 is replaced by thermal image sensor 930 (FIG. 9) or thermal image sensor 1030 (FIG. 10).

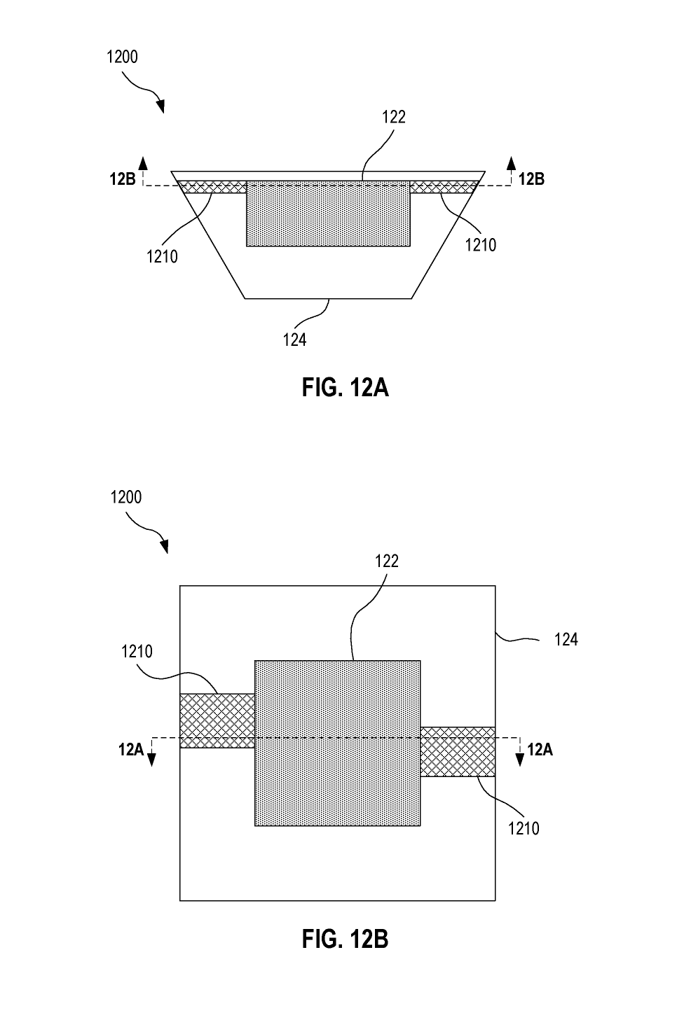

FIGS. 12A and 12B illustrate one exemplary configuration 1200 of a temperature sensitive pixel in cross-sectional side-view and cross-sectional top-view, respectively. The cross-section of FIG. 12A is taken along line 12A-12A in FIG. 12B. The cross-section of FIG. 12B is taken along line 12B-12B in FIG. 12A. Configuration 1200 is one example of how temperature sensitive pixel 122 may be suspended in pocket 124. Configuration 1200 may be implemented in thermal image sensor 120 (FIG. 1), thermal image sensor 330 (FIG. 3), thermal image sensor 630 (FIGS. 6A-6C), thermal image sensor 930 (FIG. 9), and/or thermal image sensor 1030 (FIG. 10).

In configuration 1200, temperature sensitive pixel 122 is suspended from the walls of pocket 124 via one or more mechanical support structures 1210. Although FIGS. 12A and 12B show temperature sensitive pixel 122 being suspended via two mechanical support structures 1210, configuration 1200 may utilize only one mechanical support structures 1210 or, alternatively, more than two mechanical support structures 1210, without departing from the scope hereof. Also without departing from the scope hereof, mechanical support structures 1210 may have shape and positions different from those illustrated in FIGS. 12A and 12B.

In an embodiment, mechanical support structures 1210 include electrically conductive leads that communicatively couple temperature sensitive pixel 122 with electronic circuitry external to pocket 124, such as peripheral electronic circuitry 336 (FIG. 3). In certain embodiments, mechanical support structures 1210 have low thermal conductivity to reduce or minimize thermal coupling between temperature sensitive pixel 122 and walls of pocket 124 (and other portions of the thermal image sensor in which pocket 124 is formed). Such low thermal conductivity may be achieved, for example, by (a) forming mechanical support structures 1210 from material having low thermal conductivity, (b) minimizing the cross-sectional area of mechanical support structures 1210 in plane orthogonal to the direction of heat flow between temperature sensitive pixel 122 and walls of pocket 124, and/or (c) maximizing the length of mechanical support structures 1210 to maximize the distance heat must travel to bridge the gap between temperature sensitive pixel 122 and pocket 124.

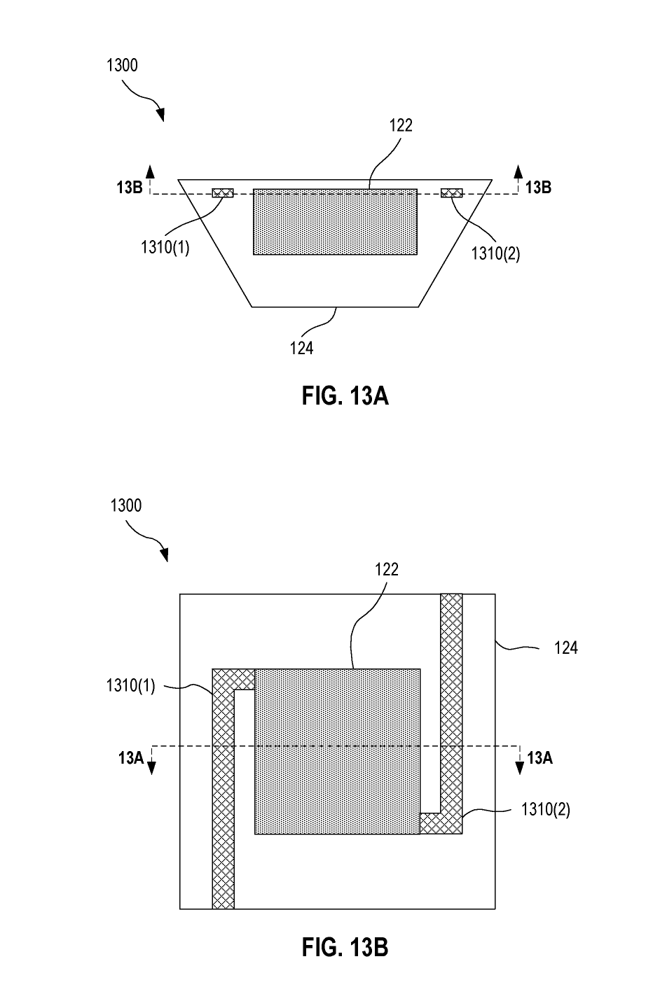

FIGS. 13A and 13B illustrate one exemplary configuration 1300 of a temperature sensitive pixel in cross-sectional side-view and cross-sectional top-view, respectively. The cross-section of FIG. 13A is taken along line 13A-13A in FIG. 13B. The cross-section of FIG. 13B is taken along line 13B-13B in FIG. 13A. Configuration 1300 is one example of how temperature sensitive pixel 122 may be suspended in pocket 124. Configuration 1300 may be implemented in thermal image sensor 120 (FIG. 1), thermal image sensor 330 (FIG. 3), thermal image sensor 630 (FIGS. 6A-6C), thermal image sensor 930 (FIG. 9), and/or thermal image sensor 1030 (FIG. 10).

In configuration 1300, temperature sensitive pixel 122 is suspended from the walls of pocket 124 via two support arms 1310. Each support arm 1310 is shaped to maximize the length of support arm 1310 and minimize the cross-sectional area of support arm 1310 in a plane orthogonal to the direction of heat flow between temperature sensitive pixel 122 and walls of pocket 124. As discussed in U.S. patent application Ser. No. 11/100,037, which is incorporated by reference herein in its entirety, configuration 1300 is compatible with CMOS manufacturing methods. Without departing from the scope hereof, support arms 1310 may have shape and positions different from those illustrated in FIGS. 13A and 13B.

Combinations of Features

Features described above as well as those claimed below may be combined in various ways without departing from the scope hereof. For example, it will be appreciated that aspects of one thermal imaging system with a vacuum-sealing lens cap or associated wafer-level manufacturing method described herein may incorporate or swap features of another thermal imaging system with a vacuum-sealing lens cap or associated wafer-level manufacturing method described herein. The following examples illustrate some possible, non-limiting combinations of embodiments described above. It should be clear that many other changes and modifications may be made to the methods and device herein without departing from the spirit and scope of this invention:

(A) A thermal imaging system with a vacuum-sealing lens cap may include a thermal image sensor, having an array of temperature sensitive pixels for detecting thermal radiation, and a lens sealed to the thermal image sensor for sealing a vacuum around the temperature sensitive pixels.

(B) In the thermal imaging system denoted as (A), the lens may be adapted to imaging thermal radiation from a scene onto the array of temperature sensitive pixels.

(C) In the thermal imaging systems denoted as (A) and (B), the lens may include silicon.

(D) In the thermal imaging systems denoted as (A) through (C), the lens may include a hot-pressed material.

(E) In the thermal imaging systems denoted as (A) through (D), the lens may include hot-pressed silicon.

(F) In the thermal imaging systems denoted as (A) through (E), the lens may consist essentially of (a) hot-pressed silicon or (b) hot-pressed silicon and one or more surface coatings.

(G) In the thermal imaging systems denoted as (A) through (F), the lens may consist of one or more materials that are at least partially transmissive to long-wavelength infrared light.

(H) In the thermal imaging systems denoted as (A) through (G), the lens may be bonded to a lens-facing side of the thermal image sensor along a path that surrounds the array of temperature sensitive pixels.

(I) In the thermal imaging system denoted as (H), the lens may have a substantially planar surface facing the array of temperature sensitive pixels, wherein the substantially planar surface may be bonded to the lens-facing side of the thermal image sensor along the path that circumnavigates the array of temperature sensitive pixels.

(J) In the thermal imaging system denoted as (I), the substantially planar surface may further contact the lens-facing side of the thermal image sensor in at least one interior location of lens-facing surface of the array of temperature sensitive pixels.

(K) In the thermal imaging system denoted as (J), for one or more of the at least one interior location, contact between the lens and the lens-facing side of the thermal image sensor may provide structural support to counteract the vacuum.

(L) In the thermal imaging systems denoted as (A) through (K), the lens may have maximum thickness, in direction orthogonal to lens-facing side of the array of temperature sensitive pixels, of less than five millimeters.

(M) In the thermal imaging systems denoted as (A) through (L), the lens may be a plano-convex lens with planar side facing the thermal image sensor.

(N) In the thermal imaging systems denoted as (A) through (L), the lens may include a concave surface facing the array of temperature sensitive pixels.

(O) The thermal imaging systems denoted as (A) through (N) may further include an adhesive material, at vacuum sealing interface between the thermal image sensor and the lens, for sealing the lens to the thermal image sensor.

(P) In the thermal imaging systems denoted as (A) through (O), the plurality of pixels may be suspended in a respective plurality of vacuum pockets in the thermal image sensor.

(Q) In the thermal imaging systems denoted as (A) through (P), the thermal image sensor may include electrical connections between the plurality of temperature sensitive pixels and electrical connection points on surface of thermal image sensor facing away from the lens.

(R) The thermal imaging systems denoted as (A) through (Q) may further include an image signal processing circuit board for performing at least one of (a) processing thermal images captured by the thermal image sensor and (b) controlling functionality of the thermal image sensor.

(S) The thermal imaging systems denoted as (A) through (Q) may further include an image signal processing circuit board for performing at least one of (a) processing thermal images captured by the thermal image sensor and (b) controlling functionality of the thermal image sensor, wherein the thermal image sensor is surface-mounted onto the image signal processing circuit board, and at least some of the electrical connection points on the surface of the thermal image sensor are in electrical contact with circuitry of the image signal processing circuit board for communicating electrical signal between the thermal image sensor and the image signal processing circuit board.

(T) A wafer-level method for manufacturing a thermal imaging system with a vacuum-sealing lens cap may include sealing a lens wafer, including a plurality of lenses, to a sensor wafer including a plurality of thermal image sensors, each thermal image sensor having an array of temperature sensitive pixels, to seal, for each of the plurality of thermal image sensors, a vacuum around the temperature sensitive pixels.

(U) The wafer-level method denoted as (T) may further include molding the lens wafer from materials at least partially transmissive to infrared light.

(V) In the wafer-level method denoted as (U), the step of molding the lens wafer may include molding a silicon lens wafer.

(W) In the wafer-level method denoted as (V), the step of molding a silicon lens wafer may include hot-pressing silicon powder in a mold shaped to form the plurality of lenses.

(X) The wafer-level methods denoted as (T) through (W) may further include molding the lens wafer.

(Y) In the wafer-level methods denoted as (T) through (X), the step of sealing may include forming a composite wafer that includes the lens wafer and the sensor wafer.

(Z) The wafer-level method denoted as (Y) may further include dicing the composite wafer to form a plurality of thermal imaging systems, wherein each of the plurality of thermal imaging systems include one of the plurality of lenses and a respective one of the plurality of thermal image sensors.

(AA) In the wafer-level methods denoted as (T) through (Z), the step of sealing may include sealing the lens wafer to the thermal image sensor wafer along paths that circumnavigate, for each of the plurality of thermal image sensors, the plurality of temperature sensitive pixels.

(AB) In the wafer-level methods denoted as (T) through (AA), the step of sealing may include sealing the lens wafer to the thermal image sensor wafer using an adhesive material.

(AC) The wafer-level methods denoted as (T) through (AB) may further include forming the thermal image sensor wafer.

(AD) In the wafer-level method denoted as (AC), the step of forming the thermal image sensor wafer may include forming the thermal image sensor wafer such that each temperature sensitive pixel of each of the plurality of thermal image sensors is suspended in a pocket of a respective one of the plurality of thermal image sensors.

Changes may be made in the above systems and methods without departing from the scope hereof. It should thus be noted that the matter contained in the above description and shown in the accompanying drawings should be interpreted as illustrative and not in a limiting sense. The following claims are intended to cover generic and specific features described herein, as well as all statements of the scope of the present system and method, which, as a matter of language, might be said to fall therebetween.

1. A thermal imaging system with a vacuum-sealing lens cap, comprising:
a thermal image sensor including an array of temperature sensitive pixels for detecting thermal radiation; and
a lens sealed directly to the thermal image sensor for imaging thermal radiation from a scene onto the array of temperature sensitive pixels and sealing a vacuum around the temperature sensitive pixels.

2. The thermal imaging system of claim 1, the lens comprising silicon.

3. The thermal imaging system of claim 2, the lens comprising hot-pressed silicon or hot-pressed ceramic powder.

4. The thermal imaging system of claim 1, the lens comprising molded plastic.

5. The thermal imaging system of claim 1, the lens consisting essentially of (a) hot-pressed silicon or (b) hot-pressed silicon and one or more surface coatings.

6. The thermal imaging system of claim 1, the lens consisting of one or more materials that are at least partially transmissive to long-wavelength infrared light.

7. The thermal imaging system of claim 6, the lens consisting of one or more materials selected from the group consisting of aluminum oxynitride, magnesium aluminate spinel, and infrared transmissive plastic.

8. The thermal imaging system of claim 1, the lens being bonded directly to a lens-facing side of the thermal image sensor along a path that surrounds the array of temperature sensitive pixels.

9. The thermal imaging system of claim 8, the lens having a substantially planar surface facing the array of temperature sensitive pixels, the thermal image sensor having a first surface closest to the substantially planar surface, the temperature sensitive pixels being recessed from the first surface in direction away from the substantially planar surface, the substantially planar surface being bonded directly to the lens-facing side of the thermal image sensor along the path that circumnavigates the array of temperature sensitive pixels, the substantially planar surface further contacting the lens-facing side of the thermal image sensor in at least one interior location of lens-facing surface of the array of temperature sensitive pixels.

10. The thermal imaging system of claim 9, wherein, for one or more of the at least one interior location, contact between the lens and the lens-facing side of the thermal image sensor provides structural support to counteract the vacuum.

11. The thermal imaging system of claim 1, the lens having maximum thickness, in direction orthogonal to lens-facing side of the array of temperature sensitive pixels, of less than five millimeters.

12. The thermal imaging system of claim 1, the lens being a plano-convex lens with planar side facing the thermal image sensor.

13. The thermal imaging system of claim 1, the lens comprising a concave surface facing the array of temperature sensitive pixels.

14. The thermal imaging system of claim 1, further comprising an adhesive material, at vacuum sealing interface between the thermal image sensor and the lens, for sealing the lens directly to the thermal image sensor.

15. The thermal imaging system of claim 1, the plurality of pixels being suspended in a respective plurality of vacuum pockets recessed in the thermal image sensor.

16. The thermal imaging system of claim 1, the thermal image sensor comprising electrical connections between the plurality of temperature sensitive pixels and electrical connection points on surface of thermal image sensor facing away from the lens.

17. The thermal imaging system of claim 16, further comprising an image signal processing circuit board for performing at least one of (a) processing thermal images captured by the thermal image sensor and (b) controlling functionality of the thermal image sensor, the thermal image sensor being surface-mounted onto the image signal processing circuit board, and at least some of the electrical connection points on the surface of the thermal image sensor being in electrical contact with circuitry of the image signal processing circuit board for communicating electrical signal between the thermal image sensor and the image signal processing circuit board.

18. A wafer-level method for manufacturing a thermal imaging system with a vacuum-sealing lens cap, comprising:
sealing a lens wafer, including a plurality of lenses, directly to a sensor wafer including a plurality of thermal image sensors, each thermal image sensor having an array of temperature sensitive pixels, to seal, for each of the plurality of thermal image sensors, a vacuum around the temperature sensitive pixels.

19. The wafer-level method of claim 18, further comprising molding the lens wafer from materials at least partially transmissive to infrared light.

20. The wafer-level method of claim 19, the step of molding the lens wafer comprising molding a silicon lens wafer.

21. The wafer-level method of claim 20, the step of molding a silicon lens wafer comprising hot-pressing silicon powder in a mold shaped to form the plurality of lenses.

22. The wafer-level method of claim 18, further comprising molding the lens wafer.

23. The wafer-level method of claim 18, further comprising molding the lens wafer using a method selected from the group consisting of isostatic pressing, die pressing, injection molding, and slip casting.

24. The wafer-level method of claim 18,
the step of sealing comprising forming a composite wafer including the lens wafer and the sensor wafer; and
the method further comprising dicing the composite wafer to form a plurality of thermal imaging systems, each of the plurality of thermal imaging systems including one of the plurality of lenses and a respective one of the plurality of thermal image sensors sealed thereto.

25. The wafer-level method of claim 18, the step of sealing comprising sealing the lens wafer directly to the sensor wafer along paths that are located around and between the thermal image sensors to circumnavigate, for each of the plurality of thermal image sensors, the plurality of temperature sensitive pixels.

26. The wafer-level method of claim 18, the step of sealing comprising sealing the lens wafer directly to the sensor wafer using an adhesive material.

27. The wafer-level method of claim 18, further comprising forming the thermal image sensor wafer, each temperature sensitive pixel of each of the plurality of thermal image sensors being suspended in a pocket recessed in a respective one of the plurality of thermal image sensors.

28. The thermal imaging system of claim 1, the thermal image sensor being formed by dicing a composite wafer, including a lens wafer and a sensor wafer, the thermal image sensor being a portion of the sensor wafer.
